(19) United States
(12) Patent Application Publication
(10) Pub. No.: US 2025/0284291 A1
(43) Pub. Date: Sep. 11, 2025

(54) Transport Facility

(71) Applicant: Daifuku Co., Ltd., Osaka-shi (JP)

(72) Inventors: Yosuke Fujiwara, Komaki-shi (JP); Yusuke Nakamura, Komaki-shi (JP); Takahiro Sebe, Komaki-shi (JP)

(21) Appl. No.: 19/069,330

(22) Filed: Mar. 4, 2025

(30) Foreign Application Priority Data
Mar. 7, 2024 (JP) 2024-034786

(51) Int. Cl. G05D 1/667; G05D 1/80; G05D 107/70

(52) U.S. Cl. CPC G05D 1/667; G05D 1/80; G05D 2107/70

(57) ABSTRACT

A transport facility includes a mobile body configured to move separately from a transport vehicle, a mobile body control system configured to control the mobile body, and a management terminal for a manager. In a case where an abnormality occurs in the transport vehicle, the mobile body control system performs an abnormality handling process of a state information acquisition device sequentially acquiring state information including a state of the transport vehicle in a state where the mobile body can acquire the state information by means of the state information acquisition device, and sequentially transmitting the acquired state information to the management terminal.

### CROSS-REFERENCE TO RELATED APPLICATION

This application claims priority to Japanese Patent Application No. 2024-034786 filed Mar. 7, 2024, the disclosure of which is hereby incorporated by reference in its entirety.

### BACKGROUND OF THE INVENTION

### 1. Field of the Invention

The present invention relates to a transport facility including a transport vehicle configured to transport a transport article.

### 2. Description of Related Art

JP 6504266 discloses an invention as an example of such a transport facility. In the invention disclosed in JP 6504266, a controller (50) communicates with a transport vehicle (20) to cause the transport vehicle (20) to transport a transport article (90). Generally, in such a transport facility, various pieces of information are exchanged by the communication between the controller and the transport vehicle.

### SUMMARY OF THE INVENTION

Information exchanged between the controller and the transport vehicle may include abnormality information on an abnormality occurring in the transport vehicle. However, there are various types of abnormalities to occur in the transport vehicle, and the transport vehicle may not grasp the occurrence of an abnormality. As a result, the controller may not be able to grasp the abnormality of the transport vehicle appropriately only by exchanging information with the transport vehicle. Besides, in a case where an abnormality occurs in a communication system between the controller and the transport vehicle, even when the transport vehicle can grasp the occurrence of an abnormality, the controller cannot receive information on the abnormality. Thus, in the transport facility in the related art, it might be difficult to appropriately grasp the state of the transport vehicle having an abnormality.

In view of such an actual circumstance, it is desired to achieve a technology that can appropriately grasp the state of a transport vehicle having an abnormality.

A technology to achieve the above object is as follows.
A transport facility includes: at least one transport vehicle configured to transport a transport article; a mobile body configured to move separately from the at least one transport vehicle; a mobile body control system configured to control the mobile body; and a management terminal for a manager. The mobile body includes a state information acquisition device configured to acquire state information on a state around the mobile body. The mobile body control system is configured to, in response to an occurrence of an abnormality in the at least one transport vehicle, perform an abnormality handling process of the state information acquisition device sequentially acquiring the state information and sequentially transmitting the acquired state information to the management terminal.

With this configuration, the mobile body can acquire state information including the state of the transport vehicle by means of the state information acquisition device. In a case where an abnormality occurs in the transport vehicle, the mobile body control system performs the abnormality handling process, and the state information including the state of the transport vehicle which state information is acquired by the mobile body is sequentially acquired by the mobile body control system and is sequentially transmitted to the management terminal. Hereby, it is not necessary for the manager to head for the site where the transport vehicle having the abnormality is present, and the manager can grasp the state of the transport vehicle appropriately.

Further features and advantages of the technology according to this disclosure will become clearer by the following illustrative and nonlimiting description of embodiments to be described with reference to the drawings.

### BRIEF DESCRIPTION OF THE DRAWINGS

FIG. 1 is a schematic view of a transport facility;

FIG. 2 is a view illustrating a transport vehicle and a mobile body;

FIG. 3 is a system configuration diagram of the transport facility;

FIG. 4 is an explanatory drawing of a pre-movement process;

FIG. 5 is an explanatory drawing of a transport article receiving process;

FIG. 6 is a drawing illustrating a process after recovery from power outage; and

FIG. 7 is a drawing illustrating a state information acquisition device being transformed.

### DESCRIPTION OF THE INVENTION

A transport facility herein is a transport facility including a transport vehicle configured to transport a transport article. With reference to the drawings, the following describes an embodiment of the transport facility.

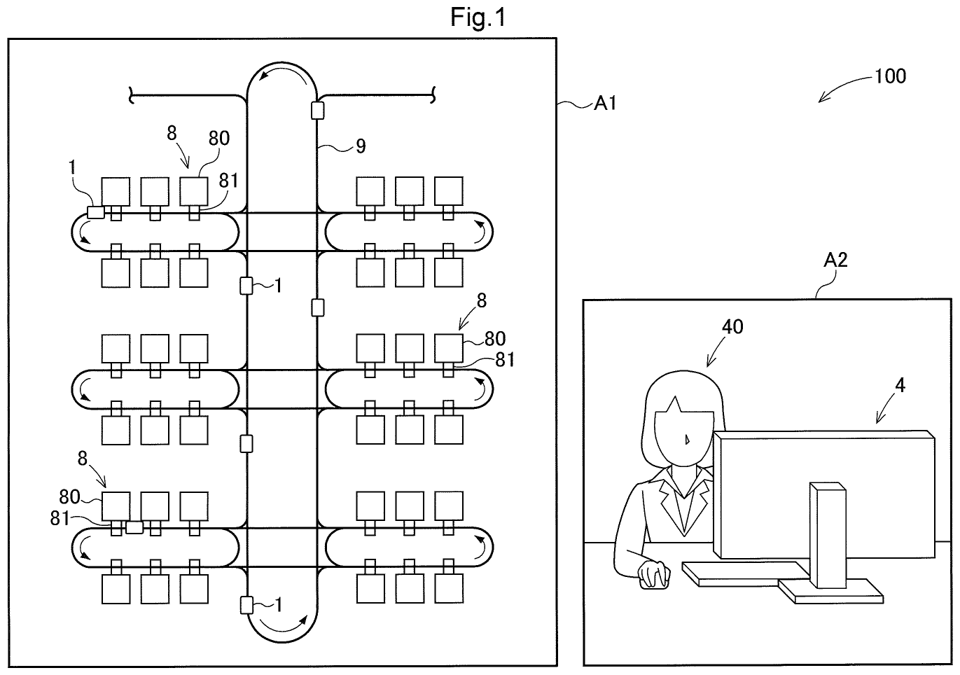

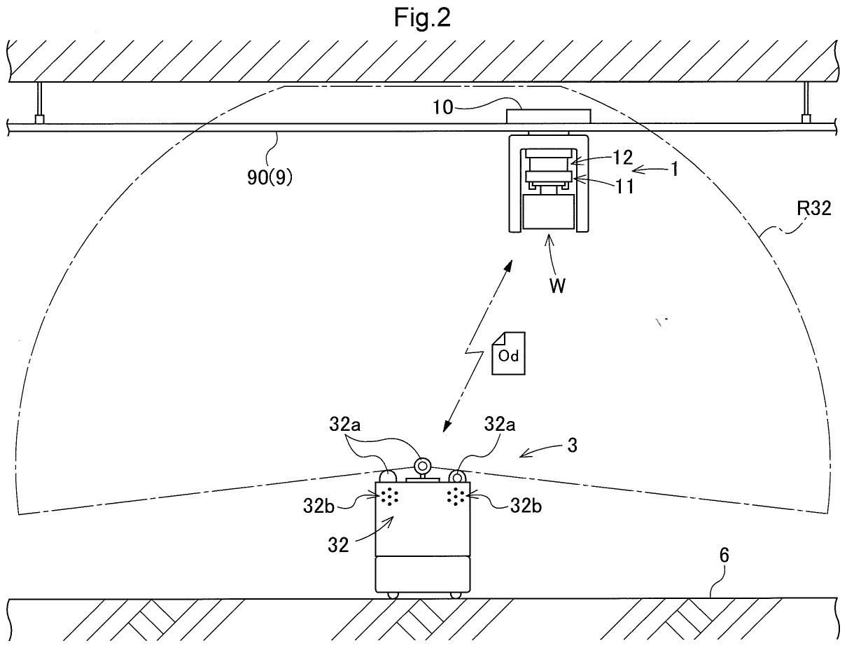

As illustrated in FIG. 1, in the present embodiment, a transport facility 100 includes a transport room A1 in which a transport article W (see FIG. 2) is transported by a transport vehicle 1, and a control room A2 in which a management terminal 4 to be operated by a manager 40 (also referred to as an “operator 40”) is installed. The control room A2 is provided outside the transport room A1. The manager 40 can come and go out between the control room A2 and the transport room A1. Note that the management terminal 4 may be a personal computer installed in the control room A2 or may be a mobile terminal (a smartphone or a tablet) portable outside the control room A2.

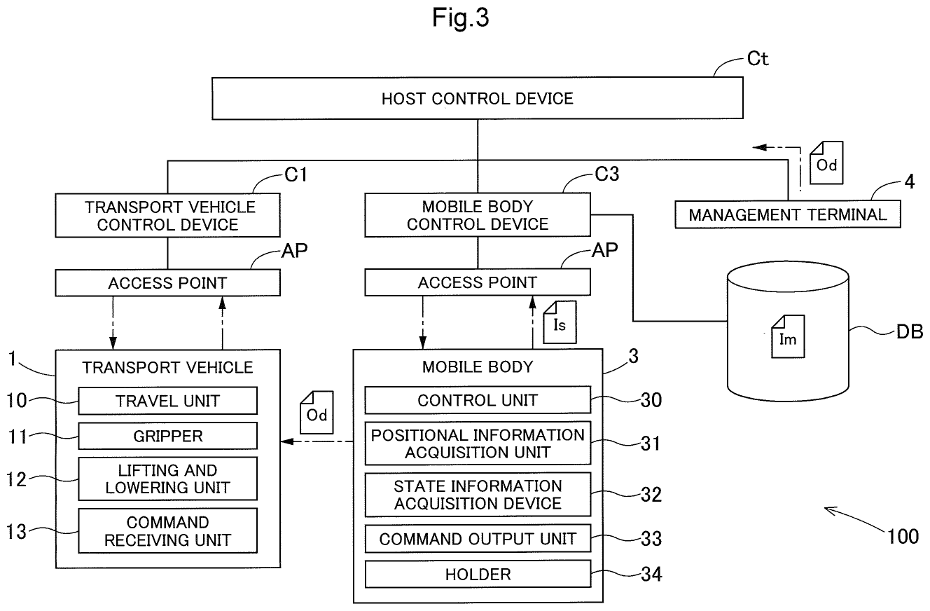

The transport facility 100 includes a plurality of transport vehicles 1 configured to travel along a path 9, and a transport vehicle control device C1 (see FIG. 3) configured to control the transport vehicle 1. The path 9 is provided for the transport room A1.

In the present embodiment, the path 9 is constituted by rails 90 (see FIG. 2) provided near a ceiling. The transport vehicle 1 is provided as a so-called overhead transport vehicle and travels on the rails 90 along the path 9.

A plurality of transfer target spots 8 is provided for the path 9. Some of the transfer target spots 8 are placed below the path 9. The transport vehicle 1 is configured to transfer the transport article W to and from the transfer target spot 8 by lifting or lowering the transport article W (see FIG. 2).

Each of the plurality of transport vehicles 1 is configured to receive a transport command from the above-mentioned transport vehicle control device C1 and to execute a task corresponding to the transport command. For example, the transport command includes information on a transport source and a transport destination of the transport article W. The transport vehicle 1 receiving the transport command transports the transport article W from the transport source to the transport destination. The transport source and the transport destination include the above-mentioned transfer target spots 8.

The transport facility 100 deals with various articles as the transport article W. In this example, the transport facility 100 is used in a semiconductor factory. Accordingly, the transport article W may be a substrate storage container (a so-called FOUP (Front Opening Unified Pod)) for storing a substrate (a wafer, a panel, or the like), a reticle storage container (a so-called reticle pod) for storing a reticle, a magazine, a tray, or the like. In this case, the transport vehicle 1 transports the transport article W such as the substrate storage container or the reticle storage container along the path 9 between steps.

In the present embodiment, the transfer target spot 8 includes a processor 80 configured to perform processing on the transport article W, and a mounting table 81 adjacent to the processor 80. The “processing on to the conveyance article” means processing on a stored object (a substrate or a reticle) stored in the transport article W as a storage container. The transport vehicle 1 receives the transport article W subjected to the processing by the processor 80 from the mounting table 81 or transfers the transport article W not subjected to the processing by the processor 80 to the mounting table 81. Note that the processor 80 performs various processes such as thin-film formation, photolithography, and etching, for example.

As illustrated in FIG. 2, the transport vehicle 1 includes a travel unit 10 configured to travel along the rail 90 constituting the path 9, and a gripper 11 configured to grip the transport article W. Hereby, the transport vehicle 1 can transport the transport article W and transfer the transport article W to and from the transfer target spot 8. In the present embodiment, the transport vehicle 1 includes a lifting and lowering unit 12 configured to lift and lower the gripper 11. Hereby, the transport vehicle 1 can transfer the transport article W to and from the transfer target spot 8 below the path 9.

As illustrated in FIG. 3, the transport facility 100 includes a host control device Ct configured to generally control each functional unit in the facility, and a transport vehicle control device C1 configured to control the transport vehicle 1. The host control device Ct and the transport vehicle control device C1 are communicably connected to each other in a wired or wireless manner.

Here, an abnormality may occur in the transport vehicle 1. A state where the transport vehicle 1 has an abnormality includes a state where the transport vehicle 1 cannot maintain its normal operation or a state where it is not appropriate to maintain the normal operation of the transport vehicle 1. For example, the abnormality of the transport vehicle 1 itself includes an operation abnormality of the travel unit 10, an operation abnormality of the gripper 11, and an operation abnormality of the lifting and lowering unit 12. An abnormality related to the transport vehicle 1 includes an abnormality of the transport article W gripped by the transport vehicle 1 (for example, in the case of FOUP, a cover is not completely closed), the presence of an obstruction around the path 9, an abnormality in electric power (shortage of electric power or excessive supply of electric power), and the like. Hereinafter, these various types of abnormalities may be just referred to as an “abnormality.”

Generally, in a case where an abnormality occurs in the transport vehicle 1, the occurrence of the abnormality and the type of the abnormality are notified by the transport vehicle 1, so that a host control system such as the host control device Ct or the transport vehicle control device C1 can grasp the occurrence of the abnormality and the type of the abnormality. However, there are various types of abnormalities to occur in the transport vehicle 1 as described above, and the transport vehicle 1 itself may not be able to grasp the occurrence of an abnormality. Because of this, the host control system may not be able to grasp the abnormality of the transport vehicle 1 appropriately only by exchanging information with the transport vehicle 1. Besides, in a case where an abnormality occurs in a communication system between the host control system and the transport vehicle 1, even when the transport vehicle 1 itself can grasp the occurrence of the abnormality, the host control system cannot receive information on the abnormality.

In view of this, the transport facility 100 according to this disclosure includes a mobile body 3 configured to move separately from the transport vehicle 1, and a mobile body control device C3 configured to control the mobile body 3. The mobile body 3 includes a state information acquisition device 32 configured to acquire state information Is on a state around the mobile body 3. The mobile body 3 is configured to be autonomously movable and can move to the vicinity of the transport vehicle 1. The mobile body 3 can acquire information on the state of the transport vehicle 1 by means of the state information acquisition device 32. Hereby, the mobile body 3 can acquire information on the transport vehicle 1 which information cannot be grasped by the host control system. The information is then transmitted to the host control system, so that the host control system or the manager 40 can appropriately grasp the state of the transport vehicle 1. A detailed description thereof is given below.

Note that, in the present embodiment, the mobile body control device C3 corresponds to a “mobile body control system.” However, the mobile body control system may be constituted by only respective control units 30 provided for a plurality of mobile bodies 3 or may include these control units 30.

As illustrated in FIG. 3, the transport facility 100 includes the mobile body control device C3 and the management terminal 4 for the manager 40 in addition to the host control device Ct and the transport vehicle control device C1. The host control device Ct, the transport vehicle control device C1, the mobile body control device C3, and the management terminal 4 are communicably connected to each other in a wired or wireless manner.

In the present embodiment, the transport vehicle control device C1 and the transport vehicle 1 are configured to communicate with each other via an access point AP. The transport vehicle control device C1 communicates with the access point AP in a wired or wireless manner. In this example, the access point AP and the transport vehicle 1 are configured to perform wireless communication. For example, they perform Wi-Fi communication®. Although details are not illustrated herein, a plurality of access points AP is provided for the transport room A1 (see FIG. 1).

The mobile body control device C3 and the mobile body 3 are configured to communicate with each other via the access point AP. The mobile body control device C3 communicates with the access point AP in a wired or wireless manner. In this example, the access point AP and the mobile body 3 are configured to perform wireless communication. For example, they perform Wi-Fi communication.

The mobile body 3 is configured to travel on a floor surface 6 (also see FIG. 2), and in the present embodiment, the mobile body 3 is a so-called AMR (Autonomous Mobile Robot).

The mobile body 3 includes a control unit 30 configured to control each functional unit of the mobile body 3, a positional information acquisition unit 31, the state information acquisition device 32, a command output unit 33, and a holder 34.

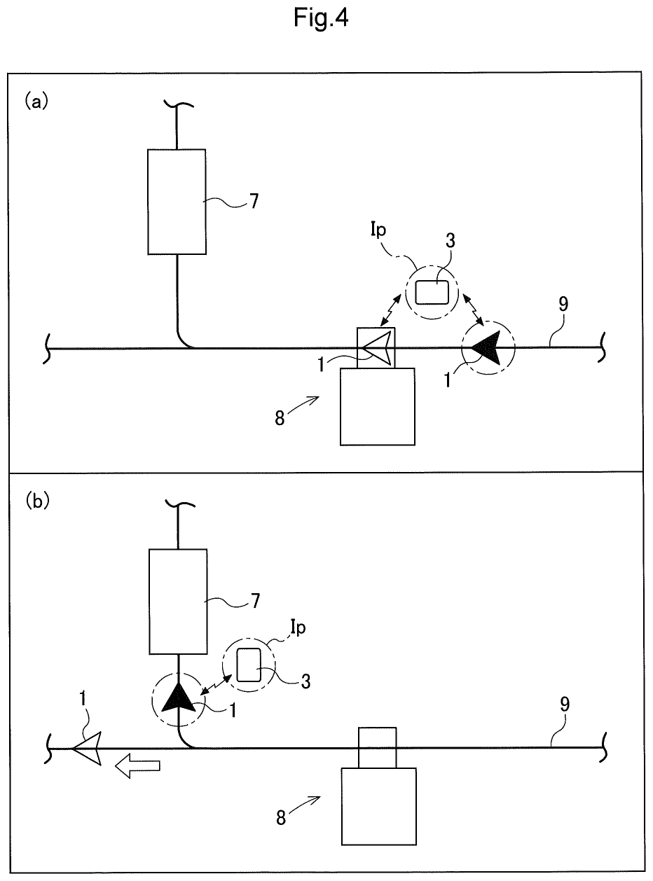

The positional information acquisition unit 31 is a functional unit configured to acquire positional information Ip (see FIG. 4) on the position of the mobile body 3 including the positional information acquisition unit 31. The mobile body 3 moves while the mobile body 3 recognizes its own position by the positional information acquisition unit 31. The recognition of the positional information is performed by the technology of mapping and self-position estimation using LiDAR (Laser Imaging Detection and Ranging) or SLAM (Simultaneous Localization and Mapping). Information acquired by the SLAM is fed back to the host control device Ct via the mobile body control device C3. Hereby, the positional information on the mobile body 3 can be shared in the whole system. In addition, the positional information may be recognized using a GPS system or a beacon system, for example. The positional information acquisition unit 31 is an element constituting at least one of these systems. Note that, in a case where the mobile body 3 moves while reading a one-dimensional code and a two-dimensional code installed in the floor surface 6, the positional information acquisition unit 31 may be constituted by a reader configured to read those codes.

The state information acquisition device 32 is a functional unit configured to acquire state information Is on a state around the mobile body 3. As illustrated in FIG. 2, the state information acquisition device 32 includes at least either a camera 32a or a microphone 32b. In the present embodiment, the state information acquisition device 32 includes both the camera 32a and the microphone 32b.

The camera 32a acquires visual information around the mobile body 3 as the state information Is. The state information Is acquired by the camera 32a includes image data such as video data or static image data. The camera 32a can function as eyes of the manager 40. The manager 40 can determine the abnormality of the transport vehicle 1 from its appearance based on the image data acquired by the camera 32a. In a case where a different operator 40 is at the site, the manager 40 can check a work of the operator 40 at the site based on the image. The mobile body 3 goes around the facility to perform monitoring during a routine transport in which the transport vehicle 1 has no abnormality, and the mobile body 3 stores image data captured by the camera 32a.

In the present embodiment, the camera 32a includes a 3600 camera that can image a wide area, and a PTZ camera having a PTZ function (Pan/Tilt/Zoom). The 360° camera functions as a camera for monitoring and for recording at the time of patrol of the mobile body 3. In a case where an abnormality occurs in the transport vehicle 1, and the mobile body 3 performs a recovery work, the 360° camera performs security monitoring around an area where the recovery work is performed. The PTZ camera is basically not used at the time of the patrol of the mobile body 3. The PTZ camera can flexibly adjust an imaging range by the PTZ function. Accordingly, in a case where an abnormality occurs in the transport vehicle 1, and the mobile body 3 performs a recovery work, the PTZ camera is helpful to image details of the transport vehicle 1 and to find a cause of the abnormality. The manager 40 can remotely operate the PTZ camera. Note that a high-performance camera having both functions of the 360° camera and the PTZ camera can be used.

The microphone 32b acquires audible information around the mobile body 3 as the state information Is. The state information Is acquired by the microphone 32b includes audio data. The microphone 32b can function as ears of the manager 40. The manager 40 can determine whether or not abnormal sound occurs along with the transport vehicle 1 working, based on the audio data or the like acquired by the microphone 32b. In a case where a different operator 40 is at the site, the manager 40 can have a conversation or the like with the operator 40 at the site and provide an appropriate instruction or the like to the operator 40 at the site. In this case, it is preferable that the mobile body 3 includes a speaker (not illustrated) configured to output voice. Hereby, it is possible to easily provide an instruction of the work to the operator 40 at the site from a place other than the site. The mobile body 3 goes around the facility to perform monitoring during a routine transport in which the transport vehicle 1 has no abnormality, and the mobile body 3 stores audio data acquired by the microphone 32b.

In the present embodiment, the state information acquisition device 32 is configured to acquire state information Is in a predetermined acquirable range R32. For example, the acquirable range R32 for the camera 32a can be expressed in other words as an imaging range. The acquirable range R32 for the microphone 32b can be expressed in other words as a sound acquisition range. The acquirable range R32 for the camera 32a and the acquirable range R32 for the microphone 32b may be the same range or may be different ranges.

The mobile body 3 comes close to the transport vehicle 1 until the transport vehicle 1 enters the acquirable range R32. Hereby, the mobile body 3 can acquire the state around the transport vehicle 1 as the state information Is.

As illustrated in FIG. 3, the mobile body control device C3 is configured to perform an abnormality handling process when an abnormality occurs in the transport vehicle 1. In the abnormality handling process, the state information acquisition device 32 sequentially acquires the state information Is in a state where the mobile body 3 can acquire the state information Is including the state of the transport vehicle 1 by means of the state information acquisition device 32, and the acquired state information Is is sequentially transmitted to the management terminal 4. In the present embodiment, the “state where the state information Is including the state of the transport vehicle 1 can be acquired” indicates that the transport vehicle 1 falls within the acquirable range R32. With the configuration, the manager 40 can grasp the state of the transport vehicle 1 appropriately without heading for the site where the transport vehicle 1 having the abnormality is present. In recent years, it has been highly demanded to easily or immediately restore the transport vehicle 1 when the transport vehicle 1 breaks. This is because a transport demand increases due to an increase in the scale of a semiconductor factory or a decrease in the lead time of a production unit. This configuration can satisfy such a demand.

In the present embodiment, the mobile body 3 is configured to be communicable with the transport vehicle 1. In the present embodiment, the mobile body 3 and the transport vehicle 1 are configured to perform short-distance wireless communication. For example, Bluetooth (registered trademark) can be used as the short-distance wireless communication. The use of equipment such as Bluetooth that is short distance communication can reduce power consumption in comparison with Wi-Fi or the like that is used for long-distance communication. However, Wi-Fi communication or infrared-ray communication are also usable.

The command output unit 33 is a functional unit configured to output an operation command Od to the transport vehicle 1. The mobile body 3 provides the operation command Od to the transport vehicle 1 to cause the transport vehicle 1 to perform a travel operation, a grip operation, a lifting and lowering operation, restart of each functional unit, and the like. The operation command Od includes a restoration operation command to restore the transport vehicle 1 from abnormality. In a case where the command output unit 33 provides a restoration operation command, the command output unit 33 causes the transport vehicle 1 to perform the travel operation, the grip operation, the lifting and lowering operation, the restart of each functional section, and the like to restore the transport vehicle 1 from an abnormal state. Hereby, it is possible to appropriately grasp which operation among the operations performed by the transport vehicle 1 has an abnormality or which functional unit among the functional units of the transport vehicle 1 has an abnormality.

For example, the manager 40 can provide the operation command Od to the transport vehicle 1 via the management terminal 4. That is, the operation command Od may include a command from the management terminal 4. Note that the operation command Od may include a command from the host control device Ct or the transport vehicle control device C1.

In the meantime, the operation command Od may be provided regardless of the intention of the manager 40. In this case, the command output unit 33 includes an automatic restoration program to generate a restoration operation command based on the state information Is acquired by the state information acquisition device 32. Hereby, the mobile body 3 can automatically perform the restoration process on the transport vehicle 1 having the abnormality. Accordingly, it is possible to reduce the time and effort for the operator 40 to perform the restoration process.

In the present embodiment, the transport vehicle 1 includes a command receiving unit 13 configured to receive the operation command Od from the command output unit 33. The transport vehicle 1 performs an operation corresponding to the operation command Od in response to the operation command Od being received by the command receiving unit 13.

As described above, in the transport facility 100 according to this disclosure, in a case where an abnormality occurs in the transport vehicle 1, the mobile body 3 acquires a state around the transport vehicle 1 as the state information Is, and the state information Is is transmitted to the management terminal 4. This allows the manager 40 to appropriately grasp the state around the transport vehicle 1 having the abnormality. Besides, the state information Is can be shared with the host control system such as the host control device Ct or the transport vehicle control device C1. This accordingly allows these host control systems to grasp detailed information that the host control systems cannot grasp, for example. The manager 40 can grasp the state around the transport vehicle 1 having the abnormality and can also remotely operate the transport vehicle 1 via the mobile body 3. Accordingly, the restoration process on the transport vehicle 1 can be also performed remotely.

Note that the mobile body 3 recognizes the occurrence of an abnormality in the transport vehicle 1 as follows, for example. As one example, an abnormality notification is transmitted from the transport vehicle 1 having the abnormality to the transport vehicle control device C1 or the host control device Ct. The abnormality notification is then transmitted to the mobile body control device C3 with positional information on the transport vehicle 1 having the abnormality. The mobile body control device C3 transmits the abnormality notification and the positional information on the transport vehicle 1 to the mobile body 3. Hereby, the mobile body 3 is notified of the occurrence of the abnormality in the transport vehicle 1 and heads for the site. As another example, the mobile body 3 going around the facility may find the transport vehicle 1 having an abnormality.

Here, as described above, the restoration operation command is transmitted from the mobile body 3 to the transport vehicle 1 to restore the transport vehicle 1 having the abnormality to a normal state. The restoration operation command is to cause the transport vehicle 1 to perform various operations or to restart or is to urge the transport vehicle 1 to switch from a maintenance mode after power outage to a normal operation mode as will be described later. However, in a case where the place (an abnormality occurrence place) where the abnormality occurs in the transport vehicle 1 is a place by which other transport vehicles 1 can pass, when the restoration operation is performed at the abnormality occurrence place, this might be obstructive to the movement of the other transport vehicles 1.

As illustrated in FIG. 4, the transport facility 100 according to this disclosure includes a predetermined maintenance area 7. The maintenance area 7 is provided on the path 9. Preferably, the maintenance area 7 is provided in a portion of the path 9 by which portion the transport vehicle 1 passes relatively less frequently. The maintenance area 7 is a place where regular maintenance or the like is performed on the transport vehicle 1 but can be utilized as a place where the restoration operation is performed on the transport vehicle 1 having the abnormality as described above.

In the present embodiment, the mobile body control device C3 is configured to perform a pre-movement process of moving the transport vehicle 1 to the predetermined maintenance area 7 and moving the mobile body 3 together with the transport vehicle 1. After the mobile body control device C3 causes the transport vehicle 1 having the abnormality to head for the maintenance area 7 by execution of the pre-movement process, the mobile body control device C3 executes the restoration process on the transport vehicle 1 at the maintenance area 7.

Here, as illustrated in FIG. 4, another normal transport vehicle 1 may be present on the path 9 along which the transport vehicle 1 having the abnormality heads for the maintenance area 7. In the figure, a black symbol indicates a target transport vehicle 1 as the transport vehicle 1 having the abnormality. A white symbol indicates the another normal transport vehicle 1.

In the present embodiment, the command output unit 33 of the mobile body 3 is also configured to output the operation command Od to the another normal transport vehicle 1. In a case where the target transport vehicle 1 as the transport vehicle 1 having the abnormality is to be moved, when another transport vehicle 1 is present on the path 9 of the target transport vehicle 1, the mobile body control device C3 outputs a move-out command to the another transport vehicle 1 on the path 9 such that the another transport vehicle 1 moves out of the path 9. The move-out command is included in the operation command Od and may be output from the command output unit 33 of the mobile body 3 to the transport vehicle 1 or may be output to the transport vehicle 1 via the host control device Ct or the transport vehicle control device C1. The “path 9 of the target transport vehicle 1” indicates a planned travel path on which the target transport vehicle 1 is to move. Accordingly, in a case where the move-out command is output, the another transport vehicle 1 to move out of the path 9 just moves outside the planned travel path on which the target transport vehicle 1 is to move, and the another transport vehicle 1 does not leave the whole path 9.

As illustrated in FIG. 4(a), in a case where there is another transport vehicle 1 on the planned travel path of the target transport vehicle 1, that is, the path 9 from a current position of the target transport vehicle 1 to the maintenance area 7, in this example, the mobile body 3 outputs a move-out command to the another transport vehicle 1. As illustrated in FIG. 4(b), the another transport vehicle 1 moves out of the planned travel path of the target transport vehicle 1.

In the meantime, the mobile body 3 causes the target transport vehicle 1 to head for the maintenance area 7. In a case where the target transport vehicle 1 heads for the maintenance area 7, the mobile body 3 moves with the target transport vehicle 1 while the mobile body 3 keeps distance from the target transport vehicle 1. This is because, when the distance between the mobile body 3 and the target transport vehicle 1 is too far, the target transport vehicle 1 may not be able to receive the operation command Od from the command output unit 33 appropriately.

Here, in a case where the content of the abnormality of the target transport vehicle 1 is an abnormality of the communication system, for example, information exchange between the host control system such as the host control device Ct or the transport vehicle control device C1 and the target transport vehicle 1 may not be performed appropriately. In this case, the host control system may not be able to grasp the position of the target transport vehicle 1.

In view of this, in the present embodiment, in a case where the target transport vehicle 1 having the abnormality is moved, the mobile body control device C3 estimates the position of the target transport vehicle 1 based on the positional information Ip on the mobile body 3, generates a route instruction command to instruct the route of the target transport vehicle 1 based on the estimated position as the operation command Od, and outputs the route instruction command from the command output unit 33. As has been described with reference to FIG. 3, the mobile body 3 includes the positional information acquisition unit 31 and can grasp its own position. In the present embodiment, the mobile body 3 is configured to acquire route information Im on the path 9 of the transport vehicle 1 and therefore can grasp its own position on the path 9. The route information Im is stored in a database DB, for example. In the example illustrated in FIG. 3, the mobile body 3 is configured to acquire the route information Im from the database DB via the mobile body control device C3. Note that the mobile body 3 may store the route information Im.

As illustrated in FIG. 4, in the present embodiment, the mobile body 3 grasps the position of the target transport vehicle 1 on the path 9 based on the position of the mobile body 3 and outputs a route instruction command to the target transport vehicle 1. In the example illustrated in FIG. 4(b), the target transport vehicle 1 changes its route to “right” and heads for the maintenance area 7 in response to the route instruction command from the mobile body 3. Note that, in a case where the transport vehicle 1 is configured to control its advancing direction by changing the position of a guide roller (not illustrated) to right and left, the route instruction command may be a signal to cause the guide roller to switch its position to right or left.

Note that the relationship between the target transport vehicle 1 and another transport vehicle 1 may be reversed to the relationship illustrated in FIG. 4. That is, in a case where the target transport vehicle 1 is located ahead of another transport vehicle 1 and is obstructive to the movement of the another transport vehicle 1, the target transport vehicle 1 may move out of a path of the another transport vehicle 1, so that the another transport vehicle 1 can secure its path.

Here, for example, in a case where the target transport vehicle 1 performs a restoration operation, it is preferable that the target transport vehicle 1 hold no transport article W. When the target transport vehicle 1 holds the transport article W, the operation to be performed by the target transport vehicle 1 may be restricted, and in such a case, it is difficult to perform an appropriate operation check.

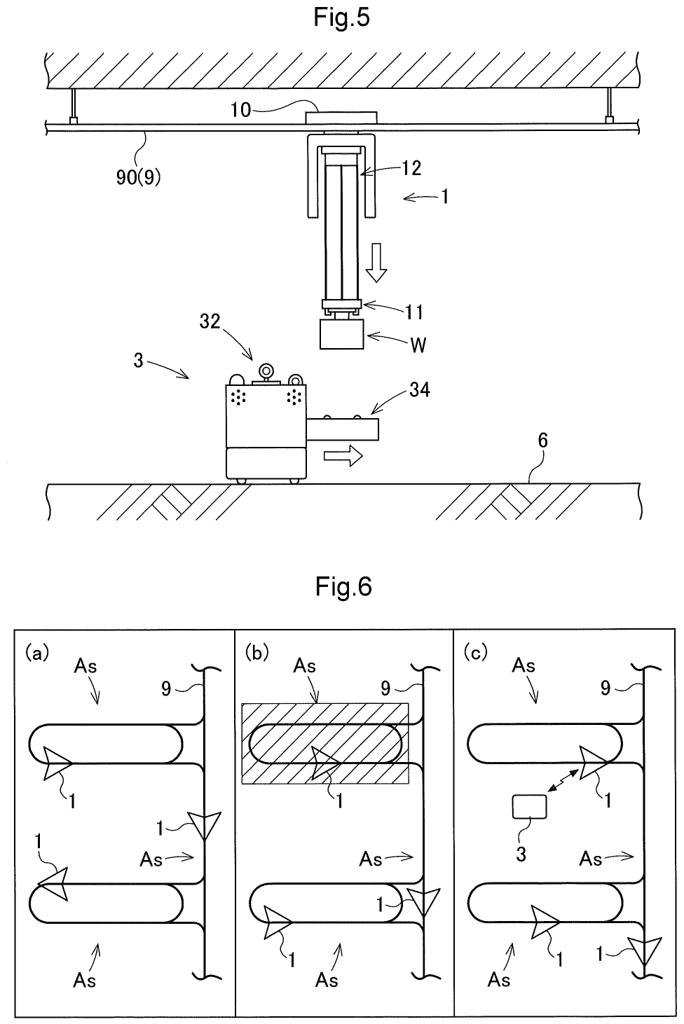

As described above, in the present embodiment, the mobile body 3 includes the holder 34 configured to hold the transport article W. As illustrated in FIG. 5, in the present embodiment, the mobile body control device C3 is configured to perform a transport article receiving process of causing the holder 34 of the mobile body 3 to receive the transport article W from the target transport vehicle 1 in a case where the target transport vehicle 1 is transporting the transport article W. Hereby, it is possible to achieve a state where the target transport vehicle 1 holds no transport article W. In the transport article receiving process, the command output unit 33 of the mobile body 3 outputs, to the target transport vehicle 1, a transfer command to transfer the transport article W. The transfer command is included in the operation command Od. The target transport vehicle 1 receiving the transfer command transfers the transport article W to the holder 34 of the mobile body 3. Note that the mobile body 3 can retract the holder 34. In cases other than a case where the transport article receiving process is performed, the mobile body 3 can retract the holder 34. However, the holder 34 may not be retractable.

It is preferable that the mobile body control device C3 execute the transport article receiving process before execution of the restoration process. Hereby, it is possible to execute the restoration process with the target transport vehicle 1 holding no transport article W and to check the operation of the target transport vehicle 1 appropriately.

In the present embodiment, a feeder cable (not illustrated) is provided along the path 9, and the transport vehicle 1 is configured to work with the use of electric power from the feeder cable as a power source. For example, as illustrated in FIG. 6, the path 9 is sectioned to setting areas As, and a power source for supplying electric power to the feeder cable is provided for each setting area As.

FIG. 6 illustrates a case where power outage occurs in a given setting area As (particularly, see FIG. 6(b)). In the present embodiment, the transport vehicle 1 in the setting area As where power outage occurs stops irregularly. When the setting area As recovers from power outage, the transport vehicle 1 shifts to a maintenance mode. For example, in the maintenance mode, a task imposed on the transport vehicle 1 before the power outage is reset or the upper limit speed of the transport vehicle 1 is set lower than that in a normal operation mode. In a case where the setting area As has power outage, generally, the host control system grasping the position of the transport vehicle 1 loses the position of the transport vehicle 1. Even in a case where the setting area As recovers from the power outage, it is difficult for the host control system once losing the position of the transport vehicle 1 to grasp the position of the transport vehicle 1 with high accuracy. Accordingly, it is difficult for the host control system to provide a shift command to the transport vehicle 1 to shift the transport vehicle 1 from the maintenance mode to the normal operation mode.

In view of this, in the present embodiment, in a case where the setting area As recovers from the power outage, and the transport vehicle 1 shifts to the maintenance mode, the command output unit 33 of the mobile body 3 outputs a mode switching command to the transport vehicle 1 (see FIG. 6(c)). The mode switching command is included in the operation command Od. In the present example, the command output unit 33 outputs the mode switching command to the transport vehicle 1 to shift the transport vehicle 1 from the maintenance mode to the normal operation mode.

In the present embodiment, in a case where the command output unit 33 outputs the mode switching command to the transport vehicle 1, the mobile body 3 estimates the position of the transport vehicle 1 based on the positional information of the mobile body 3 and notifies the host control system of information on the estimated position of the transport vehicle 1. Hereby, the host control system can appropriately grasp the position of the transport vehicle 1 after recovery from the power outage. The determination on whether or not the mode switching command is output can be remotely performed by the manager 40 after neighboring safety is confirmed based on an image captured by the camera 32a of the mobile body 3.

The above description deals with an example in which the transport vehicle 1 stops in a case where an abnormality occurs. The mobile body 3 comes close to the transport vehicle 1 until the transport vehicle 1 stopping irregularly enters the acquirable range R32, and acquires a state around the transport vehicle 1 as the state information Is (see FIG. 2).

However, depending on the layout of the facility, a structure in a place where the transport vehicle 1 stops irregularly may become an obstruction between the mobile body 3 and the transport vehicle 1, and the mobile body 3 may not acquire the state information Is appropriately.

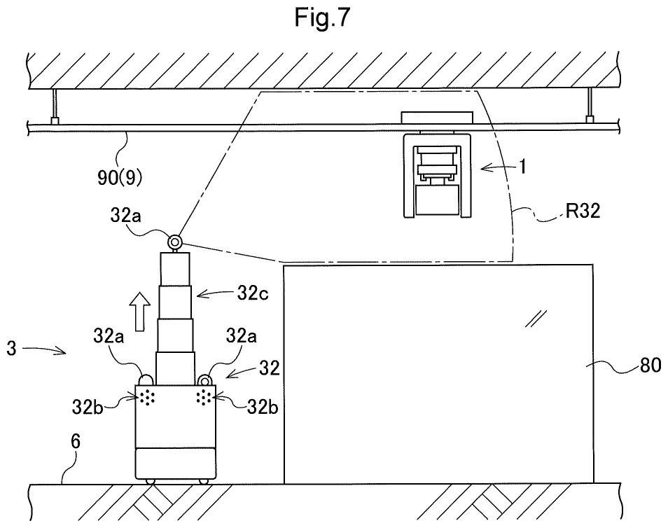

For example, in FIG. 7, the transport vehicle 1 stops above a structure (the processor 80 in the example illustrated herein). In such a case, it is difficult to cause the transport vehicle 1 to enter the acquirable range R32.

In view of this, in the present embodiment, the mobile body 3 includes a movable mechanism 32c configured to change at least either the position or the orientation of the state information acquisition device 32. Since the movable mechanism 32c changes at least either the position or the orientation of the state information acquisition device 32, even in a case where the structure is obstructive, the transport vehicle 1 stopping irregularly can enter the acquirable range R32.

In the example illustrated in FIG. 7, the movable mechanism 32c is configured to lift and lower at least part (the camera 32a in the example illustrated herein) of an element constituting the state information acquisition device 32. Hereby, the transport vehicle 1 stopping irregularly above the structure can enter the acquirable range R32, so that the mobile body 3 can acquire the state around the transport vehicle 1 as the state information Is. Note that the operation of the movable mechanism 32c may be remotely performed from management terminal 4 or may be automatically performed by the mobile body 3.

### Other Embodiments

Next will be described other embodiments.

(1) The above embodiment has described an example in which the state information acquisition device 32 includes at least either the camera 32a or the microphone 32b. However, the present invention is not limited to such an example, and the state information acquisition device 32 may include various sensors such as LiDAR, various radars, a communications device configured to communicate with the transport vehicle 1 to acquire information on the state of the transport vehicle 1, or the like.

(2) The above embodiment has described an example in which the target transport vehicle 1 transfers the transport article W to the holder 34 of the mobile body 3 in the transport article receiving process, that is, an example in which the mobile body 3 passively receives the transport article W. However, the present invention is not limited to such an example, and the mobile body 3 may actively receive the transport article W from the target transport vehicle 1 in the transport article receiving process. In this case, the mobile body 3 should include an arm, a fork, a conveyor, or the like to receive the transport article W from the target transport vehicle 1.

(3) The above embodiment has described various processes and various commands performed by the mobile body control device C3 (the mobile body control system). These various processes and various commands may be performed by the mobile body control device C3 (the mobile body control system) based on an instruction from the host control device Ct, the transport vehicle control device C1, or the management terminal 4.

(4) The above embodiment has described an example in which the transport vehicle 1 is an overhead transport vehicle. However, the present invention is not limited to such an example, and the transport vehicle 1 may be a bogie for assorting articles or may be an AGV. Alternatively, the transport vehicle 1 may be an AMR that is the same as the mobile body 3 according to the present embodiment.

(5) The above embodiment has described an example in which the mobile body 3 is an AMR. However, the present invention is not limited to such an example, and the mobile body 3 may be configured to travel on a path similar to or different from the path of the transport vehicle 1 or may be a drone or the like. The mobile body 3 may include a mounting mechanism on which the transport article W is put, and at the time of normal transport of the transport vehicle 1, the mobile body 3 may be used as a transport device for transporting the transport article W.

(6) Note that the configuration disclosed in the above embodiments can be applied in combination with the configurations disclosed in other embodiments as long as no inconsistency occurs. In terms of other configurations, the embodiments disclosed in the present specification are also just examples in all respects. Accordingly, various modifications can be made appropriately as far as it does not deviate from the scope of this disclosure.

### Overview of Embodiment

The following will describe the overview of the present embodiment.

The transport facility according to the embodiment is a transport facility including: at least one transport vehicle configured to transport a transport article; a mobile body configured to move separately from the at least one transport vehicle; a mobile body control system configured to control the mobile body; and a management terminal for a manager. The mobile body includes a state information acquisition device configured to acquire state information on a state around the mobile body. The mobile body control system is configured to, in response to an occurrence of an abnormality in the at least one transport vehicle, perform an abnormality handling process of the state information acquisition device sequentially acquiring the state information and sequentially transmitting the acquired state information to the management terminal.

With this configuration, the mobile body can acquire state information including the state of the transport vehicle by means of the state information acquisition device. In a case where an abnormality occurs in the transport vehicle, the mobile body control system performs the abnormality handling process, and the state information including the state of the transport vehicle which state information is acquired by the mobile body is sequentially acquired by the mobile body control system and is sequentially transmitted to the management terminal. Hereby, it is not necessary for the manager to head for the site where the transport vehicle having the abnormality is present, and the manager can grasp the state of the transport vehicle appropriately.

The mobile body may be communicable with the at least one transport vehicle, the mobile body may further include a command output unit configured to output an operation command to the at least one transport vehicle, and the operation command may include a restoration operation command to restore the at least one transport vehicle from the abnormality.

With this configuration, the mobile body can perform the restoration process on the transport vehicle having an abnormality. This makes it possible to reduce the time and effort required for the manager to perform the restoration process.

The operation command may include a command from the management terminal.

With this configuration, the mobile body can be remotely controlled by the intention of the manager. In a case where the operation command is a restoration command, the manager remotely operates the mobile body to perform the restoration process on the transport vehicle.

The command output unit may include an automatic restoration program to generate the restoration operation command based on the state information acquired by the state information acquisition device.

With this configuration, the mobile body can automatically perform the restoration process on the transport vehicle having an abnormality. This accordingly makes it possible to largely reduce the time and effort required for the operator to perform the restoration process.

The mobile body may include a holder configured to hold the transport article, and the mobile body control system may be configured to perform a transport article receiving process of causing the holder of the mobile body to receive the transport article from the at least one transport vehicle in a case where the at least one transport vehicle is transporting the transport article.

With this configuration, the mobile body can temporarily receive the transport article from the transport vehicle, or the mobile body can transport the transport article instead of the transport vehicle. When the mobile body receives the transport article from the transport vehicle during execution of the restoration process, it is possible to avoid the transport article from dropping off the transport vehicle by mistake.

The mobile body control system may perform a pre-movement process of moving the transport vehicle to a pre-movement process of moving the at least one transport vehicle to a predetermined maintenance area and moving the mobile body together with the at least one transport vehicle.

With this configuration, in a case where the restoration process is performed on the transport vehicle having an abnormality, it is possible to execute the restoration process after the transport vehicle is moved to the maintenance area. This according makes it possible to prevent the transport vehicle from being obstructive to another transport vehicle on the path. Since the mobile body is moved together with the transport vehicle, it is possible to appropriately grasp the state of the transport vehicle heading for the maintenance area and to appropriately output a command to the transport vehicle.

The mobile body may include: a command output unit configured to output an operation command to the transport vehicle; and a positional information acquisition unit configured to acquire positional information indicative of a position of the mobile body. In a case where the at least one transport vehicle having the abnormality is moved, the mobile body control system may estimate a position of the at least one transport vehicle based on the positional information on the mobile body, generate a route instruction command to instruct a route of the at least one transport vehicle based on the estimated position as the operation command, and output the route instruction command from the command output unit.

With this configuration, even when the position of the transport vehicle is unidentified, it is possible to instruct a route of the transport vehicle based on the positional information of the mobile body and to appropriately move the transport vehicle.

The at least one transport vehicle may include a plurality of transport vehicles, and in a case where a target transport vehicle having an abnormality is to be moved and another transport vehicle is on a path of the target transport vehicle, the mobile body control system may output, to the another transport vehicle on the path, a move-out command to move the another transport vehicle out of the path.

With this configuration, even in a case where there is another transport vehicle on the path of the target transport vehicle having an abnormality, it is possible to appropriately move the target transport vehicle.

The state information acquisition device may include at least one of a camera and a microphone, and the mobile body may include a movable mechanism configured to change at least either a position or an orientation of the state information acquisition device.

With this configuration, it is possible to acquire the state information as visual information or audible information. When the movable mechanism changes the position or the orientation of the state information acquisition device, it is possible to improve acquisition accuracy of the visual information or the audible information. Accordingly, for example, even in a case where there is an obstruction or the like between the mobile body and the transport vehicle, it is possible to appropriately acquire the state information.

### INDUSTRIAL APPLICABILITY

The technology according to this disclosure can be used for a transport facility including a transport vehicle configured to transport a transport article.

What is claimed is:

1. A transport facility, comprising:
at least one transport vehicle configured to transport a transport article;
a mobile body configured to move separately from the at least one transport vehicle;
a mobile body control system configured to control the mobile body; and
a management terminal for a manager,
wherein the mobile body comprises a state information acquisition device configured to acquire state information on a state around the mobile body, and
wherein the mobile body control system is configured to, in response to an occurrence of an abnormality in the at least one transport vehicle, perform an abnormality handling process of the state information acquisition device sequentially acquiring the state information and sequentially transmitting the acquired state information to the management terminal.

2. The transport facility according to claim 1, wherein:
the mobile body is communicable with the at least one transport vehicle,
the mobile body further comprises a command output unit configured to output an operation command to the at least one transport vehicle, and
the operation command comprises a restoration operation command to restore the at least one transport vehicle from the abnormality.

3. The transport facility according to claim 2, wherein:
the operation command comprises a command from the management terminal.

4. The transport facility according to claim 2, wherein:
the command output unit comprises an automatic restoration program to generate the restoration operation command based on the state information acquired by the state information acquisition device.

5. The transport facility according to claim 1, wherein:
the mobile body comprises a holder configured to hold the transport article, and
the mobile body control system is configured to perform a transport article receiving process of causing the holder of the mobile body to receive the transport article from the at least one transport vehicle in a case where the at least one transport vehicle is transporting the transport article.

6. The transport facility according to claim 2, wherein:
the mobile body control system performs a pre-movement process of moving the at least one transport vehicle to a predetermined maintenance area and moving the mobile body together with the at least one transport vehicle.

7. The transport facility according to claim 2, wherein:
the mobile body comprises a positional information acquisition unit configured to acquire positional information on a position of the mobile body, and
in a case where the at least one transport vehicle having the abnormality is moved, the mobile body control system estimates a position of the at least one transport vehicle based on the positional information on the mobile body, generates a route instruction command to instruct a route of the at least one transport vehicle based on the estimated position as the operation command, and outputs the route instruction command from the command output unit.

8. The transport facility according to claim 1, wherein:
the at least one transport vehicle comprises a plurality of transport vehicles, and
in a case where a target transport vehicle having an abnormality is to be moved and another transport vehicle is on a path of the target transport vehicle, the mobile body control system outputs, to the another transport vehicle on the path, a move-out command to move the another transport vehicle out of the path.

9. The transport facility according to claim 1, wherein:
the state information acquisition device comprises at least either a camera or a microphone, and
the mobile body comprises a movable mechanism configured to change at least either a position or an orientation of the state information acquisition device.
